(19) United States
(12) Patent Application Publication
(10) Pub. No.: US 2009/0236757 A1
(43) Pub. Date: Sep. 24, 2009

(54) SEMICONDUCTOR DEVICE AND METHOD FOR MANUFACTURING

(75) Inventors: Manfred Mengel, Bad Abbach (DE); Joachim Mahler, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 12/053,830

(22) Filed: Mar. 24, 2008

(51) Int. Cl. H01L 23/12; H01L 21/58

(52) U.S. Cl. 257/783; 438/117; 257/E23.003; 257/E23.193; 257/E21.505

(57) ABSTRACT

A semiconductor device and method for manufacturing. One embodiment includes a carrier, a structured layer arranged over the carrier and a semiconductor chip applied to the structured layer. The structured layer includes a first structure made of an elastic material and a second structure made of an adhesive material.

### BACKGROUND

The invention relates to a semiconductor device and a method for manufacturing a semiconductor device.

Semiconductor for devices may include homogeneous composite materials like adhesives on which the semiconductor chip is applied. Such homogeneous composite materials illustrate homogeneous material characteristics.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1A schematically illustrates a cross-section of device 100 as one embodiment.

FIG. 1B schematically illustrates a cross-section of device 100 as one embodiment.

FIG. 1C schematically illustrates plan view of device 100 as illustrated in FIG. 1B, wherein the chip is not depicted.

FIG. 2 schematically illustrates a cross-section of device 200 as one embodiment.

FIG. 3 schematically illustrates a cross-section of device 300 as one embodiment.

FIGS. 4A to 4C schematically illustrate a method to fabricate a device 400 illustrated in a cross-sectional view.

FIGS. 5A to 5F schematically illustrate a method to fabricate a device 500 illustrated in a cross-sectional view.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

In addition, while a particular feature or aspect of an embodiment may be disclosed with respect to only one of several implementations, such feature or aspect may be combined with one or more other features or aspects of the other implementations as may be desired and advantageous for any given or particular application. It is to be appreciated that features and elements depicted herein are illustrated with particular dimensions relative to one another for purposes of simplicity and ease of understanding, and that actual dimensions may differ substantially from that illustrated herein.

Devices including semiconductor chips are described. The described embodiments do not depend on the specific embodiment of the semiconductor chips. The semiconductor chips are of arbitrary type and may, for example, include integrated electrical, electro-optical circuits, control circuits, microprocessors or micro-electromechanical components. The semiconductor chips do not need to be manufactured from a specific semiconductor material, for example, they may be made of Si, SiC, SiGe or GaAs. They may be configured as power semiconductor devices such as power transistors, power diodes or IGBTs (Insulated Gate Bipolar Transistors). Further, the semiconductor chips may contain inorganic or organic materials that are not semiconductors, such as for example insulators, plastics or metals. The semiconductor chips may be packaged or unpackaged.

The semiconductor devices further include a carrier, wherein the described aspects do not depend on the specific embodiment of the carrier. The carrier may be of any shape, size or material. During the fabrication of the semiconductor devices the carrier may be provided in a way that other carriers are arranged in the vicinity and are connected by connection means to the carrier with the purpose of separating the carriers. The carrier may be fabricated from metals or metal alloys, for example copper, copper alloys, iron nickel, aluminum, aluminum alloys, or other materials. It may be electrically conductive. Furthermore, the carrier may be plated with an electrically conductive material, for example copper, silver, iron nickel or nickel phosphorus. The carrier may, for example, be a leadframe or a part of a leadframe, such as a die pad or any other rigid substrate. In one embodiment, the carrier may also be made of an insulating material, for example a ceramic.

The semiconductor devices may include a structure made of an elastic material. The elastic material may, for example, include silicone, polybutadiene or an elastomer. The elastic material is preferably configured to provide a buffer function in order to absorb pressure, stress or tension that may occur during the fabrication or the operation of the device. In this manner, possible device damage (material breakage, cohesive breakage, delamination, etc.) in certain areas of high pressure, stress or tension can be avoided. The material characteristics of the elastic material may thus be selected according to a certain manufacturing method or specific conditions during the operation of the device. The elastic material may be arranged and localized at specific locations of the device in order to increase its buffer function at these locations. Moreover, the concentration of the elastic material may be adjusted in a selective way according to the desired strength of its buffer effect. It is understood that the devices may include multiple structures made of elastic materials with the multiple structures differing in their respective material characteristics.

The semiconductor devices may further include a structure including filler particles. The filler particles may be fabricated from a ceramic material, in one embodiment oxides, such as silicon oxide, aluminum oxide, zirconium oxide or titanium oxide, or nitrides, such as silicon nitride. The filler particles may also be fabricated from any other inorganic material capable of forming ceramics, in one embodiment glasses, such as silicon dioxide. The particles may further be fabricated from organic materials, such as polyimides. The filler particles may be of arbitrary shape and different sizes, for example they may be ball-shaped with a diameter smaller than 5 micrometers. The arrangement and material characteristics of the filler particles may be configured to increase the break strength of the structure that includes the filler particles. In this manner, damage during the fabrication or operation of the device is avoided. Such material properties may, for example, be the thermodynamical, electrical, mechanical or thermomechanical characteristics of the filler particles. The filler particles may be arranged and localized at selected locations of the device. It is understood that the device may includes multiple structures including filler particles each of which may include filler particles of different concentrations.

The devices may further include a structure including an adhesion promoter material. The structure may be arranged in the form of an adhesion promoter layer that preferably contacts a carrier or a semiconductor chip of the device. The structure may be configured to improve adhesion between different components of the device. Material properties of the adhesion promoter material, like thermodynamical, electrical, mechanical or thermomechanical characteristics may be chosen according to its specific application, for example according to the components whose in-between adhesion is to be improved. The thickness of an adhesion promoter layer is use-oriented and in one embodiment may be smaller than 10 nanometers. The adhesion promoter material may include a silane. It is understood that the device may includes multiple structures including an adhesion promoter material with each structure having different material characteristics.

The semiconductor devices may further include a structure including a resin. The resin may be embodied as a base polymer matrix and may include a thermosetting resin like an epoxy and/or an acrylate and/or polyimide and/or silicone and/or a thermoplastic polymer and/or a high-temperature thermoplastic polymer. The material properties of the resin, like thermodynamical, electrical, mechanical or thermomechanical characteristics may be chosen according to the specific application of the device and conditions appearing during its operation. In one embodiment, the resin is configured to provide adhesive properties. It is understood that the device may include multiple structures including a resin with each of structure having different material characteristics.

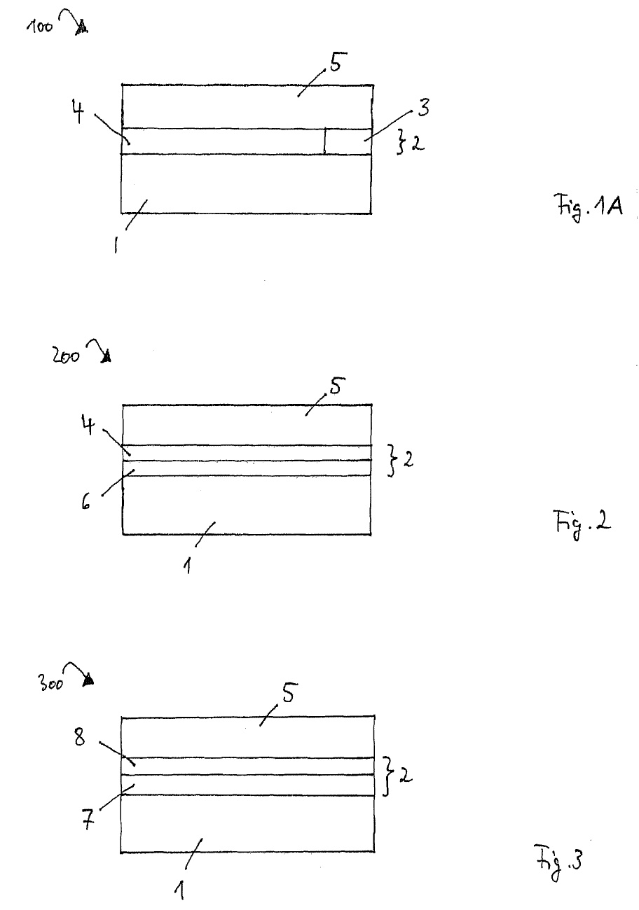

FIG. 1A schematically illustrates a device 100 as an exemplary embodiment. The device 100 includes a carrier 1 and a structured layer 2 arranged over the carrier 1. The structured layer 2 includes a first structure 3 made of an elastic material and a second structure 4 made of an adhesive material. That is, the first and second structures 3, 4 are made of different materials and have different physical characteristics in view of elasticity and adhesive strength. A semiconductor chip 5 is applied to the structured layer 2. Since the structured layer 2 includes the two different structures 3 and 4, its overall structure is inhomogeneous. In the case of the device 100, the structure 3, 4 are located laterally adjacent to each other such that a lateral section through the structured layer 2 exhibits two sectional surfaces each having an area which is smaller than the main surface area of the structured layer 2.

The first structure 3 made of an elastic material may be arranged at one or more edges of the structured layer 2. In this case, its desired buffer function is localized at the edge of the structured layer 2. In one manner the first structure 3 may e.g., be situated like a ring or frame which encloses the second structure 4 totally from the outer sides, see FIGS. 1B and 1C. A pressure, stress or tension occurring at the edge of the structured layer 2 may therefore be buffered in an optimal and improved way. In this manner, damage of the device 100 can be avoided. Depending on the specific strength of the possibly occurring pressure, stress or tension, the first structure 3 may be adjusted concerning its material properties. It is understood that the first structure 3 may also be arranged at other or further locations of the structured layer 2 depending on the need to increase stress absorption or pressure absorption at such selected locations. The height and form of the first structure 3 generally depends on the device under consideration. In one embodiment, the height of the first structure 3 is less than 100 micrometers and in one embodiment lies in a range from 1 to 20 micrometers.

FIGS. 1A to 1C do not explicitly illustrate the inner composition of the second structure 4 made of an adhesive material. The second structure 4 may be manufactured homogeneously, for example by a resin, but may also include further materials, like for example filler particles. The optional employment of filler particles provides the possibility of adjusting the desired material characteristics of the second structure 4.

The structured layer 2 has improved characteristics over a conventional composite layer in which the elastic material component and the adhesive material component are homogeneously distributed.

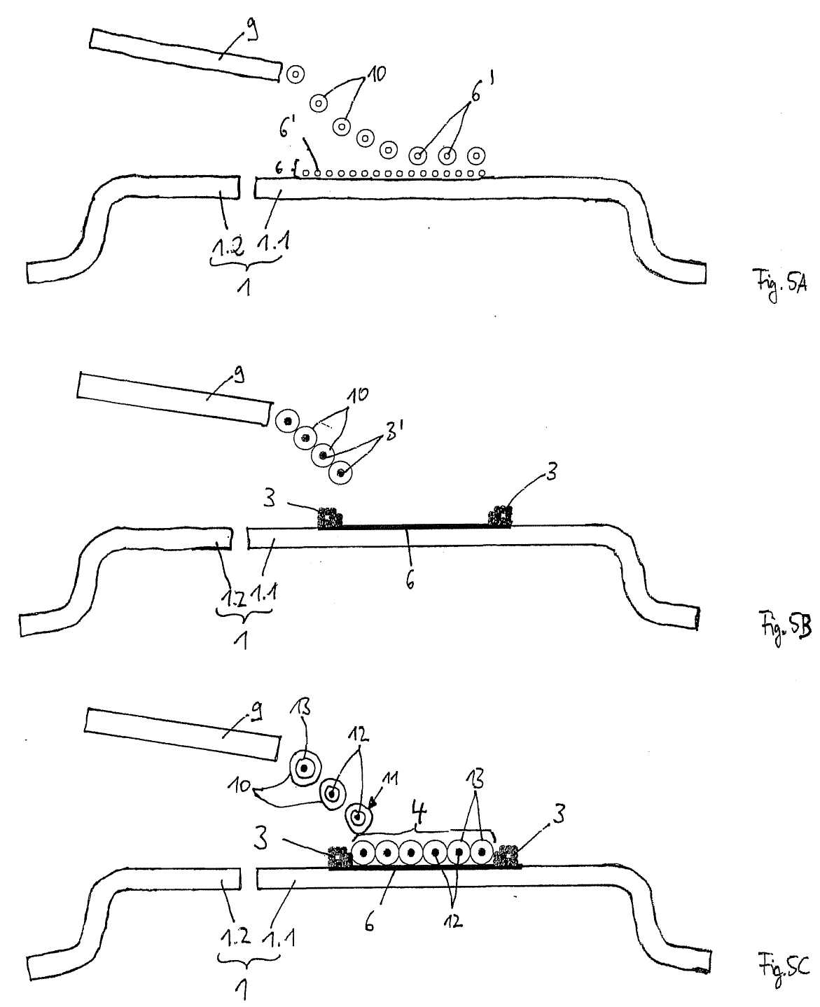

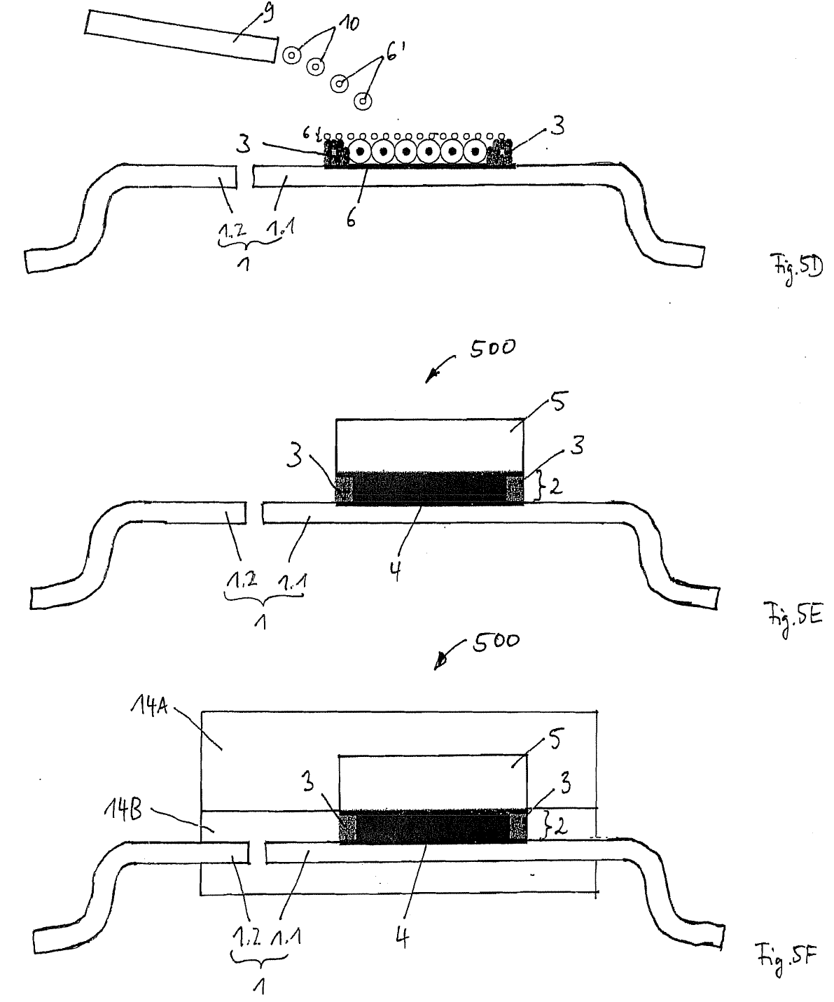

A method of manufacturing a device 400 similar to the device 100 is illustrated in FIGS. 4A to 4C. A method of manufacturing a device including components similar to the components of the device 100 is illustrated in FIGS. 5A to 5F.

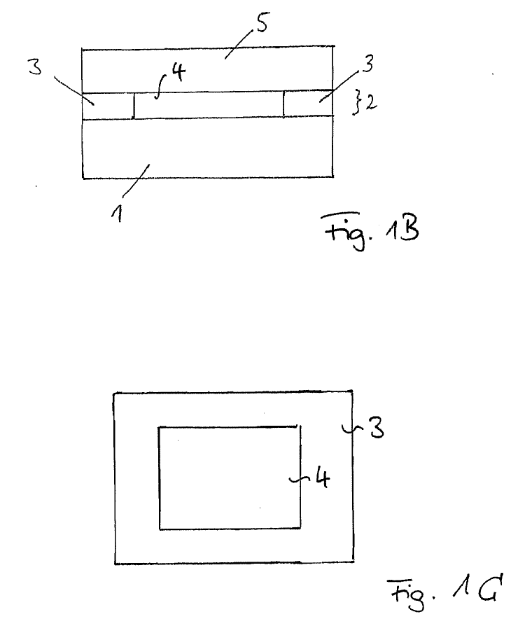

FIG. 2 schematically illustrates a device 200 as one embodiment. The device 200 includes a carrier 1 and a structured layer 2 arranged over the carrier 1. The structured layer 2 includes a first structure 6 made of an adhesion promoter material and a second structure 4 made of an adhesive material. The first and second structures 6, 4 are made of different materials and have different physical characteristics in view of adhesive promotion capability and adhesive strength. A semiconductor chip 5 is applied to the structured layer 2. Since the structured layer 2 includes two different structures 4 and 6, its overall structure is inhomogeneous. Structures 4, 6 are arranged one upon the other. In case of the device 200, the area of a main surface of each structure 4 and 6 may equal the area of a main surface of the structured layer 2. It is understood that the areas of a main surface of the structures 4 and 6 may also be smaller than the area of a main surface of the structured layer 2.

The first structure 6 made of an adhesion promoter material provides an improved adhesion between the carrier 1 and the second structure 4 made of an adhesive material. By applying the first structure 6 at selected locations of the device 200, desired promotion of adhesion between the carrier 1 and the second structure 4 made of the adhesive material may be localized and increased at such locations. Depending on the desired adhesion strength of the first structure 6 made of an adhesion promoter material, its material properties may be adjusted. The thickness of the first structure 6 depends on the specific device under consideration. In one embodiment, the thickness of the first structure 6 may be smaller than 10 nanometers.

FIG. 2 does not explicitly illustrate the inner composition of the second structure 4 made of an adhesive material. The second structure 4 made of an adhesive material may be manufactured homogeneously, for example, by a resin, but may also include further materials, like for example filler particles. Again, the optional employment of filler particles provides the possibility of adjusting the material characteristics of the second structure 4.

The structured layer 2 has improved characteristics over a conventional composite layer in which the adhesive material component and the adhesion promoter material component are homogeneously distributed. By dividing the conventional adhesive composite material into an adhesion layer (i.e. second structure 4) and an adhesion promoter layer (i.e. first structure 6), a higher concentration of adhesion promoter at the boundary region will result in a higher adhesion strength of adhesive material to carrier. Further, the choice of adhesion promoter can be adapted to the chosen carrier material.

A method of manufacturing a device including components similar to the components of the device 200 is illustrated in FIGS. 5A to 5F.

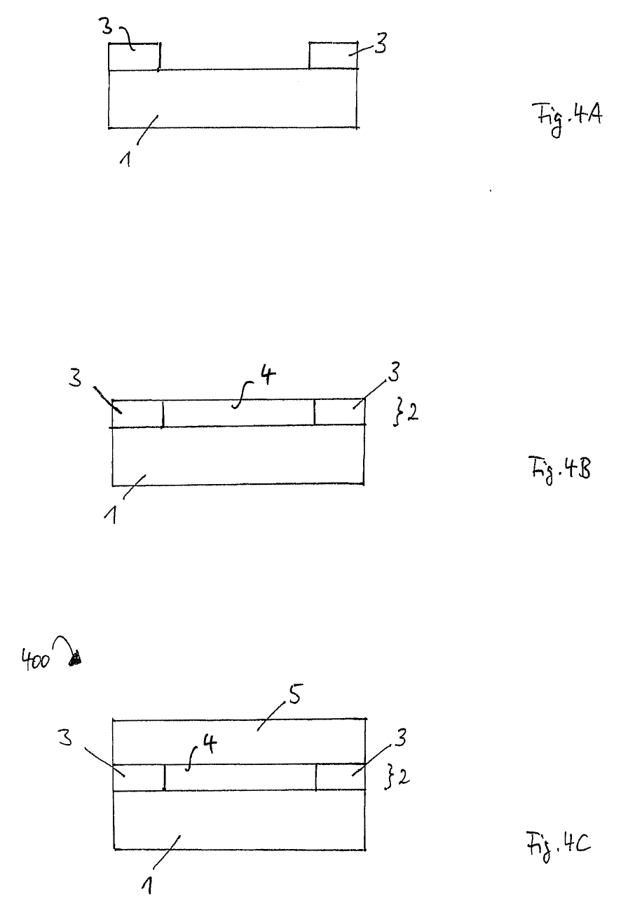

FIG. 3 schematically illustrates a device 300 as a further exemplary embodiment. The device 300 includes a carrier 1 and a structured layer 2 arranged over the carrier 1. The structured layer 2 is an adhesive layer made of a resin and includes a first structure 7 and a second structure 8 having different concentrations and/or types of filler particles. Filler particles of different types are particles having different sizes or shapes or are made of different materials. A semiconductor chip 5 is applied to the structured layer 2. Since the structured layer 2 includes two different structures 7 and 8, its overall structure is inhomogeneous. In case of the device 300, the area of a main surface of each structure 7 and 8 may equal the area of a main surface of the structured layer 2. It is understood that the areas of a main surface of structures 7 and 8 may also be smaller than the area of a main surface of the structured layer 2.

The carrier 1 and the semiconductor chip 5 may differ in their material characteristics, for example regarding their individual thermal expansion coefficient or their mechanical stability or stiffness. By changing the concentrations and/or types of the filler particles in the first structure 7, its material characteristics may be adjusted to the material characteristics of the carrier 1. In a similar way, the material characteristics of the second structure 8 may be adjusted to the material characteristics of the semiconductor chip 5. These adjustments preferably lead to a reduced pressure, stress or tension at the contact area between the first structure 7 and the carrier 1 and a reduced pressure, stress or tension at the contact area between the second structure 8 and the semiconductor chip 5. Thus, the structured layer 2 has improved material characteristics over a conventional composite layer in which the filler particles are homogeneously distributed. Instead of two layers consisting of the first structure 7 and the second structure 8, an arrangement of multiple layer structures with gradually changing thermal expansion coefficients or mechanical stabilities (such as stiffnesses) may work even more effectively as a stress or tension buffer.

A further improvement of the mechanical stability of the package can be reached by locally concentrate filler particles differently not only in the vertical direction but also in the lateral dimension of the layers of the first structure 7 and/or the second structure 8 especially at the edges, e.g., by designing the first and/or second structure 7, 8 similar to the structured layer 2 illustrated in FIGS. 1A to 1C. In this case, the concepts of lateral and vertical structuring in view of different concentrations and/or types of filler particles are combined. Further, it is possible that only lateral structuring is applied according to FIGS. 1A to 1C.

Besides the changing of concentrations and/or types of filler particles, an adjustment to the material characteristics could also be performed by varying the polymer network density resulting in locally different mechanical stiffnesses. Structures of different network densities may be reached by applying differently concentrated polymers and/or crosslinking agents and or curing procedures. Again, the structured layer 2 may be made to be a vertical or lateral or combined vertical-lateral structure analogous to the above description.

FIGS. 4A to 4C schematically illustrate an exemplary method to fabricate a device 400. The device 400 includes similar components as the device 100. Accordingly, above given comments concerning components of device 100 also hold true for the corresponding components of device 400.

FIG. 4A illustrates a first method process of manufacturing the device 400 illustrated in FIG. 4C. A carrier 1 is provided and a first structure 3 made of an elastic material is arranged over the carrier. For example, the first structure 3 may be deposited by using a printing method, in one embodiment an ink jet or screen printing method. The elastic material to be deposited may be applied by using a nozzle or an applicator (not illustrated) that includes an aperture out of which the material is applied. Possible printing methods may differ in the utilized applicator and the diameter of its aperture. Drops of the applied printing material may therefore differ in their diameters.

For example, applying a Jet-Dispense method, the diameter of the applicator's aperture may be about 100 micrometers. Using a nanolithography method, in one embodiment a DPN (Dip Pen Nanolithography) method, the diameter of the applicator's aperture may be smaller than 0.1 micrometers. The selected printing method depends on the desired dimensions of the first structure 3 made of an elastic material that is to be deposited. During the deposition, the first structure 3 made of an elastic material may be selectively placed at such locations of the device 400 at which an increased amount of stress or pressure is to be expected.

FIG. 4B illustrates a second method process of manufacturing the device 400. A second structure 4 made of an adhesive material is arranged over the carrier 1. The described methods of manufacturing the first structure 3 (cf. description of FIG. 4A) may also be employed in the fabrication of the second structure 4. However, it is understood that the structures 3 and 4 may each be manufactured using different methods which preferably depend on the desired dimensions of the structures. It is to be noted that the deposition of the structures 3 and 4 may be accomplished simultaneously or successively. Similar to the first structure 3 made of an elastic material the second structure 4 made of an adhesive material may selectively be placed at desired locations during its deposition. The structures 3 and 4 form a laterally structured layer 2. The shape of the first structure 3 could be like a frame or ring layer around the chip area in the middle as illustrated in FIGS. 4A to 4C.

FIG. 4C illustrates a third method process of manufacturing the device 400, wherein a semiconductor chip 5 is attached to the structured layer 2. Adhesion between the semiconductor chip 5 and the structured layer 2 is provided by the second structure 4 made of an adhesive material.

FIGS. 5A to 5F schematically illustrate an exemplary method to fabricate a device 500. Devices 100 to 400 may includes similar components. Accordingly, the above comments concerning components of devices 100 to 400 also hold true for the corresponding components of device 500.

FIG. 5A illustrates a first method process of manufacturing the device 500. A carrier 1 is provided. As already noted, the carrier 1 may be of arbitrary form. In FIG. 5A, the carrier 1 includes a die pad area 1.1 and a pin 1.2 which are connected according to the specific geometry of the carrier 1 (e.g., a leadframe). The die pad area 1.1 and the pin 1.2 may both be used to provide an electrical connection between a semiconductor chip (not illustrated) of the device 500 and a possible external application, like a printed circuit board (PCB).

First particles 6′ made of adhesion promoter material are deposited over the carrier 1 using an applicator 9. The specific embodiment of the applicator 9, in one embodiment its size and the size of an aperture out of which the particles 6′ are applied depends on the desired dimension of an adhesion promoter layer 6 that is to be formed by the adhesion promoter particles 6′. The thickness of the adhesion promoter layer 6 may be smaller than 10 nanometers and the lateral dimension of the adhesion promoter layer 6 may be at least the size of the semiconductor chip 5 to be attached later. The applicator 9 may be an inkjet printing device. As an alternative technique, spray coating or plasma deposition could be used.

During depositing the adhesion promoter particles 6′, the particles 6′ may be dispersed in a liquid 10. In FIG. 5A the liquid 10 is indicated by circles encircling the adhesion promoter particles 6′. The liquid 10 is configured to prevent premature agglomeration of the adhesion promoter particles 6′ and may include acetone, ethanol, toluene or any other solvent. The adhesion promoter particles 6′ are dispersed in the liquid 10 when deposited, wherein the liquid evaporates prior to or during the formation of the adhesion promoter layer 6. To accelerate the evaporation process a heating of the carrier 1 could be performed in parallel. Preferably, the liquid 10 is chosen to be chemically compatible with properties of the adhesion promoter particles 6′. Further, the viscosity of the liquid 10 preferably supports the deposition of the adhesion promoter particles 6′. It is to be noted that the employment of the liquid 10 is optional. If the viscosity of the adhesion promoter particles 6′ is low enough for an appropriate deposition over the carrier 5, the usage of the liquid 10 may be omitted. After deposition of adhesion promoter particles a certain drying period could be added.

FIG. 5B illustrates a second method process of manufacturing the device 500. Second particles 3′ made of an elastic material are deposited on the adhesion promoter layer 6 using an applicator 9. The second particles 3′ may be applied only to specific locations on the adhesion promoter layer 6, e.g., may be heaped on a peripheral portion of the carrier 1 in order to form locally confined cushion structures beneath the semiconductor chip 5. In one manner this cushion structure can be laterally arranged like a ring or frame enclosing the subsequently applied adhesive structure 4. The specific embodiment of the applicator 9, in one embodiment its size and the size of its aperture out of which the particles 3′ are applied depends on the desired dimension of the first structure 3 that is to be formed by the second particles 3′. In one embodiment, the height of the first structure 3 may be less than 100 micrometers and particularly may lie in a range from 1 to 20 micrometers. It is to be noted that the printing methods applied in FIGS. 5A and 5B do not need to be identical, but may rather depend on the desired dimensions of the structures 3 and 6. Accordingly, the applicator 9 of FIG. 5B needs not to coincide with the applicator 9 of FIG. 5A.

Similar to the first method process of FIG. 5A the second particles 3′ made of an elastic material may be dispersed in a liquid 10 during their deposition over the carrier 1. The liquid 10 of FIG. 5B is configured to provide similar functions as the liquid 10 of FIG. 5A. Thus, all comments made in connection with FIG. 5A also hold true for the liquid 10 of FIG. 5B. It is understood that the liquid 10 of FIG. 5A needs not to be identical to the liquid 10 of FIG. 5B. Preferably, the liquid 10 of FIG. 5B depends on the chemical and mechanical properties of the second particles 3′. Again, the usage of the liquid 10 is optional.

FIG. 5C illustrates a third method process of manufacturing the device 500. Particles 11 are deposited over the carrier 1 onto the adhesion promoter layer 6 and the first structure 3 made of the second particles 3′ using an applicator 9. Each particle 11 is illustrated by two circles enclosing a filled out circle. The filled out circle illustrates filler particles 12, the circle encircling the filler particle 12 illustrates a resin 13 and the outermost circle illustrates a liquid 10. All comments made on the applicator 9 and the liquid 10 of FIGS. 5A and 5B hold true for FIG. 5C as well. The filler particles 12 and the resin 13 form an adhesive second structure 4 after the optional liquid 10 has been evaporated. The particles 11 may be deposited between the two first structures 3 made of an elastic material. In FIG. 5C, the filler particles 12 are embedded in the resin 13. In one embodiment, the filler particles 12 and the resin 13 may be arranged as separate layers. This may be advantageous for the case of the filler particles 12 and the resin being chemically incompatible to each other. Instead of a one layer structure 4, an arrangement of multiple layer structures with gradually changing thermal expansion coefficients or mechanical stabilities (such as stiffnesses) by way of different filler concentrations and/or types may work even more effectively as a stress or tension buffer.

It is to be noted that the first structure 3 made of an elastic material does not only provide an increased buffer function at the edges of the structured layer 2. It further acts as a barrier to prevent the particles 11 from flowing onto the carrier 1. The first structure 3 may thus be referred to as a “bleed-out barrier” or a “dam-and-fill structure”.

FIG. 5D illustrates a fourth method process of manufacturing the device 500. First particles 6′ made of adhesion promoter material are deposited over the carrier 1 using an applicator 9. The method process of FIG. 5D corresponds to the method process of FIG. 5A. Accordingly, any comments on FIG. 5A also hold true for FIG. 5D. It is understood that the specific choice of the adhesion promoter layer 6 applied in FIG. 5D may differ from the one illustrated in FIG. 5A. In one embodiment, the adhesion promoter layer 6 is adjusted to the properties of the semiconductor chip 5 that is applied in the method process of FIG. 5E.

FIG. 5E illustrates a fifth method process of manufacturing the device 500. A semiconductor chip 5 is applied to the structured layer 2. Further, the structured layer 2 including the components described in previous method processes 5A to 5D is cured using an arbitrary curing method.

FIG. 5F illustrates a sixth method process of manufacturing the device 500. A molding material including a bottom structure 14A and a top structure 14B is applied to the device 500 with the purpose of packaging the part of the carrier 1 on which the semiconductor chip 5 is placed. The structures 14A and 14B may be composed of an appropriate thermoplastic or thermosetting material, in one embodiment they may be composed of material commonly used in contemporary semiconductor packaging technology such as e.g., epoxy. The structures 14A and 14B may also be made of a resin including filler particles. They may particularly be configured to prevent the device 500 to be penetrated by humidity.

In case of the structures 14A and 14B including filler particles, the structures 14A and 14B may differ in their respective concentrations and/or types of filler particles. By adjusting the concentrations of filler particles, the material characteristics of the structures 14A and 14B may be adjusted in a desired way. In one embodiment, the material characteristics of the first structure 14A contacting the semiconductor chip 5 may be adjusted to the material characteristics of the semiconductor chip 5. In a similar way, the material characteristics of the second structure 14B contacting the carrier 1 may be adjusted to the material characteristics of the carrier 1. In this manner, pressure, stress or tension occurring at the contact area between the bottom structure 14A and the semiconductor chip 5 and at the contact area between the top structure 14B and the carrier 1 may be absorbed and reduced. For example, the thermal expansion coefficient of the structure 14A covering the semiconductor chip 5 may be smaller than 10 ppm/K and the thermal expansion coefficient of the structure 14B covering the carrier 1 may be greater than 10 ppm/K. Only a single material (e.g., one of the type referred to above) for the structures 14A and 14B could be used, which then form only one common structure.

The employment of various structures having different concentrations and/or types of filler particles may also be applied for manufacturing the adhesive second structure 4 or further coatings or passivation layers (not illustrated) of the device 500. For example, the adhesive second structure 4 may be composed of e.g., laterally adjacent different zones made of the same base polymer material matrix but being provided with filler particles of different concentrations and/or types. Or such laterally adjacent different zones of the adhesive second structure 4 consist of different polymer types having different thermomechanical properties like epoxy, polyimide or acrylate or different thermosetting and/or thermoplastic polymers. As a further example, layers having different concentrations and/or types of filler particles may also coat the semiconductor chip 5 and act as a passivation layer, a buffer layer or an encapsulation. Further, as has been explained with regard to FIGS. 1A to 3, the structured layer 2 may be of a much simpler design containing as few as only two structures of different materials, resulting in that various method processes illustrated in FIGS. 5A to 5F may be omitted.

Methods for manufacturing devices similar to the devices 200 and 300 are not explicitly illustrated. It is however understood that the method processes described in connection with the production of devices 400 and 500 may also be applied to fabricate devices similar to the devices 200 and 300. In one embodiment, a selective deposition and localization of materials by employing one of the described techniques (e.g., an ink jet method) may be applied.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising:
a carrier;
a structured layer arranged over the carrier; and
a semiconductor chip applied to the structured layer, wherein the structured layer comprises a first structure made of an elastic material and a second structure made of an adhesive material.

2. The semiconductor device of claim 1, comprising wherein the surface area of at least one of the first structure and the second structure is smaller than the surface area of the structured layer.

3. The semiconductor device of claim 1, comprising wherein the first structure is arranged at an edge of the structured layer.

4. The semiconductor device of claim 1, comprising wherein the height of the first structure is less than 100 micrometers and in particular lies in a range from 1 to 20 micrometers.

5. The semiconductor device of claim 1, wherein the first structure comprises at least one of polybutadiene, a silicone, and an elastomer.

6. The semiconductor device of claim 1, wherein the second structure comprises at least one of resin particles and filler particles.

7. The semiconductor device of claim 6, comprising wherein the filler particles are embedded in the resin.

8. The semiconductor device of claim 6, comprising wherein the resin and the filler particles are arranged as layers.

9. The semiconductor device of claim 6, wherein the resin comprises at least one of an epoxy, an acrylate and a thermoplastic.

10. The semiconductor device of claim 6, wherein the filler particles comprise at least one of a metal oxide, a silicon oxide, a ceramic, a glass and a polymer.

11. The semiconductor device of claim 1 further comprising:
a third layer made of an adhesion promoter material.

12. The semiconductor device of claim 11, comprising wherein the third layer contacts the carrier or the semiconductor chip.

13. The semiconductor device of claim 11, wherein the third layer comprises a silane.

14. A method comprising:
arranging a first structure made of an elastic material over a carrier;
arranging a second structure made of an adhesive material over the carrier, the first and the second structure forming a structured layer; and
applying a semiconductor chip to the structured layer.

15. The method of claim 14, comprising depositing at least one of the first structure and the second structure using a printing method.

16. The method of claim 14, comprising depositing the at least one of the first structure and the second structure by using a nanolithography method.

17. The method of claim 14, comprising simultaneous arranging the first structure and the second structure over the carrier.

18. The method of claim 14, comprising successively arranging the first structure and the second structure over the carrier.

19. The method of claim 14, further comprising:
curing the structured layer.

20. The method of claim 14, further comprising:
depositing first particles to form the first structure;
depositing second particles to form the second structure; and
dispersing the first and second particles in a liquid when deposited, wherein the liquid evaporates prior to the formation of the first structure or the second structure.

21. A semiconductor device comprising:
a carrier;
a structured layer arranged over the carrier; and
a semiconductor chip applied to the structured layer, wherein the structured layer comprises a first structure made of an adhesion promoter material and a second structure made of an adhesive material.

22. The semiconductor device of claim 21, wherein the first structure comprises a silane;
the second structure comprises at least one of resin particles and filler particles, wherein
the resin comprises at least one of an epoxy, an acrylate and a thermoplastic; and
the filler particles comprise at least one of a metal oxide, a silicon oxide, a ceramic, a glass and a polymer.

23. A semiconductor device comprising:
a carrier;
a structured layer arranged over the carrier; and
a semiconductor chip applied to the structured layer, wherein the structured layer is an adhesive layer made of a resin and comprises a first structure and a second structure having different concentrations of filler particles.

24. The semiconductor device of claim 23, wherein the resin comprises at least one of an epoxy, an acrylate and a thermoplastic; and
the filler particles comprise at least one of a metal oxide, a silicon oxide, a ceramic, a glass and a polymer.

25. A semiconductor device comprising:
a carrier;
means for providing a structured layer arranged over the carrier; and
a semiconductor chip applied to the structured layer, wherein the structured layer comprises means for providing a first structure made of an elastic material and means for providing a second structure made of an adhesive material.
